(19) United States
(12) Patent Application Publication
(10) Pub. No.: US 2025/0214114 A1
(43) Pub. Date: Jul. 3, 2025

(54) SUBSTRATE CLEANING HEAD, SUBSTRATE CLEANING MODULE INCLUDING THE SAME, SUBSTRATE CLEANING SYSTEM INCLUDING THE SAME, AND SUBSTRATE PROCESSING METHOD USING THE SAME

(71) Applicant: Samsung Electronics Co., Ltd., Suwon-si (KR)

(72) Inventors: SANGJINE PARK, Suwon-si (KR); HYOUNGGEUN PARK, Suwon-si (KR); Ji Hwan PARK, Suwon-si (KR)

(73) Assignees: Samsung Electronics Co., Ltd., Suwon-si (KR); SEMES CO., LTD., Cheonan-si (KR)

(21) Appl. No.: 18/921,720

(22) Filed: Oct. 21, 2024

(30) Foreign Application Priority Data
Dec. 27, 2023 (KR) 10-2023-0193238
Jan. 12, 2024 (KR) 10-2024-0005430

(51) Int. Cl. B08B 1/12; B08B 1/36; B08B 3/02

(52) U.S. Cl. CPC B08B 1/12; B08B 1/36; B08B 3/02

(57) ABSTRACT

Disclosed are substrate cleaning heads, substrate cleaning modules, substrate cleaning systems, and substrate processing methods. The substrate cleaning head comprises a support body having a vertical axis, and a plurality of brushes at a bottom surface of the support body, wherein the brushes of the plurality of brushes are arranged in a circumferential direction about the vertical axis of the support body. The brushes of the plurality of brushes are each spaced apart from one another in the circumferential direction. Each of the brushes includes a brush body that extends in the circumferential direction from a first side surface to a second side surface opposing the first side surface, and an inclination portion extending inward from an inner lateral extent of the brush body. A thickness of the inclination portion decreases in an inward direction. An inclined surface as a bottom surface of the inclination portion forms an acute angle with the vertical axis.

### CROSS-REFERENCE TO RELATED APPLICATIONS

This U.S. nonprovisional application claims priority under 35 U.S.C § 119 to Korean Patent Applications No. 10-2023-0193238 filed on Dec. 27, 2023, and No. 10-2024-0005430 filed on Jan. 12, 2024, in the Korean Intellectual Property Office, the disclosures of which are hereby incorporated by reference in their entirety.

### BACKGROUND

The present inventive concepts relate to a substrate cleaning head, a substrate cleaning module including the same, a substrate cleaning system including the same, and a substrate processing method using the same, and more particularly, to a substrate cleaning head capable of uniformly cleaning a substrate, a substrate cleaning module including the same, a substrate cleaning system including the same, and a substrate processing method using the same.

A semiconductor device may be fabricated through various processes. For example, the semiconductor device may be manufactured through a photolithography process, an etching process, a deposition process, a cleaning process, and a plating process on a substrate. A substrate cleaning process may be performed prior to other processes. For example, the substrate may be cleaned before an exposure process is executed on the substrate. In detail, a photoresist (PR) material is coated on the substrate, and then an inactive surface of the substrate may be cleaned before an exposure process is fulfilled on the substrate. Various apparatuses may be used to clean the substrate. For example, a nozzle may be used to spray a fluid onto the substrate, and a substrate cleaning head may be utilized which is in direct contact with the substrate.

### SUMMARY

Some embodiments of the present inventive concepts provide a substrate cleaning head configured to uniformly pressurizes a substrate to prevent a contaminant from remaining on a specific position on the substrate, a substrate cleaning module including the same, a substrate cleaning system including the same, and a substrate processing method using the same.

Some embodiments of the present inventive concepts provide a substrate cleaning head capable of preventing a substrate from being contaminated back in a cleaning procedure, a substrate cleaning module including the same, a substrate cleaning system including the same, and a substrate processing method using the same.

Some embodiments of the present inventive concepts provide a substrate cleaning head capable of preventing a substrate from being damaged in a cleaning procedure, a substrate cleaning module including the same, a substrate cleaning system including the same, and a substrate processing method using the same.

The object of the present inventive concepts is not limited to the mentioned above, and other objects which have not been mentioned above will be clearly understood to those skilled in the art from the following description.

According to some embodiments of the present inventive concepts, a substrate cleaning head may comprise: a support body having a vertical axis; and a plurality of brushes at a bottom surface of the support body. The brushes of the plurality of brushes are arranged in a circumferential direction about the vertical axis of the support body. The brushes of the plurality of brushes may be spaced apart from one another in the circumferential direction. Each brush of the plurality of brushes may include: a brush body that extends in the circumferential direction from a first side surface to a second side surface opposing the first side surface; and an inclination portion extending inward from an inward lateral extent of the brush body. A thickness of the inclination portion may decrease in an inward direction toward a center of the support body. An inclined surface as a bottom surface of the inclination portion may from an acute angle with the vertical axis.

According to some embodiments of the present inventive concepts, a substrate cleaning module may comprise: a substrate cleaning head configured to cleans a surface of a substrate; a cleaning arm supporting the substrate cleaning head and configured to move the substrate cleaning head in a horizontal direction; a pressure sensor that is connected to the substrate cleaning head and configured to measure a pressure applied to the substrate cleaning head; and a pressurization actuator that connected to the substrate cleaning head and drives the substrate cleaning head to move vertically. The substrate cleaning head may include: a support body; and a brush on a bottom surface of the support body.

According to some embodiments of the present inventive concepts, a substrate cleaning system may comprise: a stage that supports a substrate; a substrate cleaning module on the stage; and a cleaning solution injection device above the stage and spaced apart in a horizontal direction from the substrate cleaning module. The substrate cleaning module may include: a substrate cleaning head; and a cleaning arm that supports the substrate cleaning head. The substrate cleaning head may include: a support body; and a plurality of brushes on a bottom surface of the support body and each brush of the plurality of brushes spaced apart from one another in a circumferential direction about a vertical axis of the support body. The support body may have a fluid supply channel that penetrates the support body in a vertical direction from a top surface to a bottom surface. The cleaning arm may have a fluid delivery path connected to the fluid supply channel.

According to some embodiments of the present inventive concepts, a substrate processing method may comprise: placing a substrate on a stage of a substrate cleaning system; and cleaning the substrate on the stage. The step of cleaning the substrate may include: moving a substrate cleaning head to contact a top surface of the substrate, the substrate cleaning head being upwardly spaced apart from the stage; moving the substrate cleaning head in a horizontal direction; and measuring a pressure applied to the substrate cleaning head.

Details of other example embodiments are included in the description and drawings.

### BRIEF DESCRIPTION OF DRAWINGS

FIG. 1 is a cross-sectional view showing a substrate cleaning system according to some embodiments of the present inventive concepts.

FIG. 2 is an enlarged cross-sectional view showing detail X of FIG. 1.

FIG. 3 is a cross-sectional view showing a substrate cleaning module according to some embodiments of the present inventive concepts.

FIG. 4 is an enlarged cross-sectional view showing detail Y of FIG. 3.

FIG. 5 is a perspective view showing a substrate cleaning head according to some embodiments of the present inventive concepts.

FIG. 6 is a bottom view showing a substrate cleaning head according to some embodiments of the present inventive concepts.

FIG. 7 is a cut perspective view showing a substrate cleaning head according to some embodiments of the present inventive concepts.

FIG. 8 is a cross-sectional view showing a substrate cleaning head according to some embodiments of the present inventive concepts.

FIG. 9 is a flow chart showing a substrate processing method according to some embodiments of the present inventive concepts.

FIG. 10 is a flow chart showing a substrate processing method according to some embodiments of the present inventive concepts.

FIGS. 11, 12, 13, 14, 15, and 16 are diagrams showing the operation of a substrate cleaning apparatus during a substrate processing method according to the flow chart of FIG. 10.

### DETAILED DESCRIPTION OF EMBODIMENTS

The following will now describe some embodiments of the present inventive concepts with reference to the accompanying drawings. Like reference numerals may indicate like components throughout the description. Although the figures described herein may be referred to using language such as “one embodiment,” or “certain embodiments,” these figures, and their corresponding descriptions are not intended to be mutually exclusive from other figures or descriptions, unless the context so indicates. Therefore, certain aspects from certain figures may be the same as certain features in other figures, and/or certain figures may be different representations or different portions of a particular exemplary embodiment.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Spatially relative terms, such as “beneath,” “below,” “lower,” “above,” “upper,” “top,” “bottom,” and the like, may be used herein for ease of description to describe positional relationships, such as illustrated in the figures, for example. It will be understood that the spatially relative terms encompass different orientations of the device in addition to the orientation depicted in the figures.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

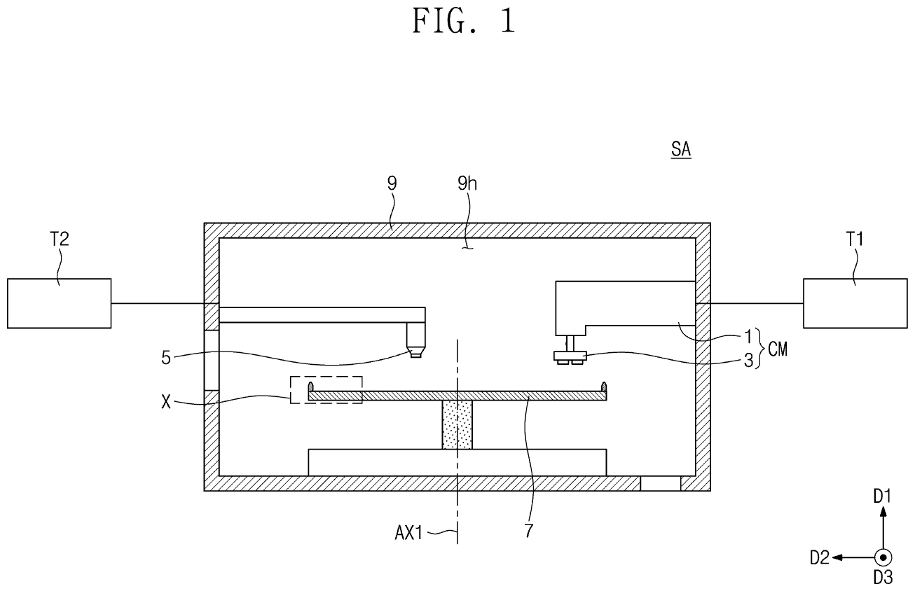

FIG. 1 is a cross-sectional view showing a substrate cleaning system according to some embodiments of the present inventive concepts.

In this description, symbol D1 may indicate a first direction, symbol D2 may indicate a second direction that intersects the first direction D1, and symbol D3 may indicate a third direction that intersects each of the first direction D1 and the second direction D2. Each of the first direction D1, second direction D2, and third direction D3 may be perpendicular to one another. The first direction D1 may be called a vertical direction or an upward direction. In addition, each of the second direction D2 and the third direction D3 may be called a horizontal direction.

Referring to FIG. 1, a substrate cleaning system SA is shown. The substrate cleaning system SA may be used to clean a substrate. The term “substrate” as used in this description may refer to a silicon (Si) wafer, but the present inventive concepts are not limited thereto. The substrate cleaning system SA may clean a substrate prior to other processes being performed on the substrate. For example, the substrate cleaning system SA may clean a substrate prior to an exposure process. In detail, a photoresist (PR) material may be coated on the substrate, and then the substrate cleaning system SA may clean the substrate before the substrate is inserted into an exposure apparatus. The present inventive concepts, however, are not limited thereto, and the substrate cleaning system SA may clean a substrate before a photoresist material is coated on the substrate. Alternatively, or in addition to, the substrate cleaning system SA may clean a substrate prior to other processes. Alternatively, or in addition to, the substrate cleaning system SA may clean a substrate after other processes are performed.

The substrate cleaning system SA may clean an inactive surface of a substrate. Thus, a substrate inserted into the substrate cleaning system SA may be disposed to allow its inactive surface to face upwards. A top surface of a substrate inserted into the substrate cleaning system SA may be an inactive surface of the substrate. A bottom surface of a substrate inserted into the substrate cleaning system SA may be an active surface of the substrate. In this sense, the substrate cleaning system SA may be an apparatus for cleaning an inactive surface of a substrate. The substrate cleaning system SA may include a cleaning chamber 9, a stage 7, a substrate cleaning module CM, a cleaning solution injection device 5, a first fluid supply T1, and a second fluid supply T2.

The cleaning chamber 9 may have a cleaning space 9h. For example, the cleaning chamber 9 may have an internal cavity for receiving a substrate to be cleaned. A substrate may undergo a cleaning process in a state in which the substrate is disposed in the cleaning chamber 9 (e.g., disposed in the cleaning space 9h).

The stage 7 may be located in the cleaning chamber 9. For example, the stage 7 may be located in the cleaning space 9h. The stage 7 may support a substrate in the cleaning chamber 9. The stage 7 will be discussed in further detail below.

The substrate cleaning module CM may be positioned above the stage 7. For example, the substrate cleaning module CM may be disposed to be spaced apart from the stage 7 in the first direction. The substrate cleaning module CM may be movable in the cleaning chamber 9. The substrate cleaning module CM may include a cleaning arm 1 and a substrate cleaning head 3. The cleaning arm 1 may support the substrate cleaning head 3. The cleaning arm 1 may allow the substrate cleaning head 3 to move in the cleaning chamber 9. For example, the cleaning arm 1 may have at least one joint allowing the cleaning arm, and therefore the substrate cleaning head 3, to move. Or, in another example, the cleaning arm may remain fixed and the cleaning head 3 may be secured to the cleaning arm through a joint allowing the cleaning head to move relative to the cleaning arm. In another example, a combination of joints of the cleaning head and the cleaning arm may be used to allow the cleaning head to move. For example, a sliding joint may allow the substrate cleaning head 3 to move in a horizontal direction. The sliding joint may allow the cleaning head to slide along a lower surface of the cleaning arm. Or the sliding joint may allow the cleaning arm to slide horizontally. The substrate cleaning head 3 may be connected under the cleaning arm 1. The substrate cleaning head 3 may clean a substrate supported on the stage 7. For example, the substrate cleaning head 3 may directly contact and clean a substrate supported on the stage 7. The substrate cleaning module CM will be discussed in further detail below.

The cleaning solution injection device 5 may be positioned over the stage 7. For example, the cleaning solution injection device 5 may be disposed spaced apart from the stage 7 in the vertical direction. The cleaning solution injection device 5 may be spaced apart in a horizontal direction from the substrate cleaning module CM. The cleaning solution injection device 5 may spray a fluid onto a substrate supported on the stage 7 when the cleaning solution injection device 5 is operated. The cleaning solution injection device 5 may include a nozzle and a nozzle arm that supports the nozzle. The cleaning solution injection device 5 will be further discussed in detail below.

The first fluid supply T1 may be connected to the substrate cleaning module CM. For example, the first fluid supply T1 may have a pipeline providing a path for a fluid to travel from the first fluid supply T1 to the cleaning module CM. The first fluid supply T1 may supply the substrate cleaning module CM with a first fluid. The first fluid supplied from the first fluid supply T1 may be sprayed from the substrate cleaning module CM onto a substrate supported on the stage 7. The first fluid supply T1 may include a fluid tank, a compressor, and a pipeline. The first fluid supply T1 will be further discussed in detail below.

The second fluid supply T2 may be connected to the cleaning solution injection device 5. For example, the second fluid supply T2 may have a pipeline providing a path for a fluid to travel from the second fluid supply T2 to the cleaning solution injection device 5. The second fluid supply T2 may supply the cleaning solution injection device 5 with a second fluid. The second fluid supplied from the second fluid supply T2 may be sprayed by the cleaning solution injection device 5 onto a substrate supported on the stage 7. The second fluid supply T2 may include a fluid tank, a compressor, and a pipeline. The second fluid supply T2 will be further discussed in detail below.

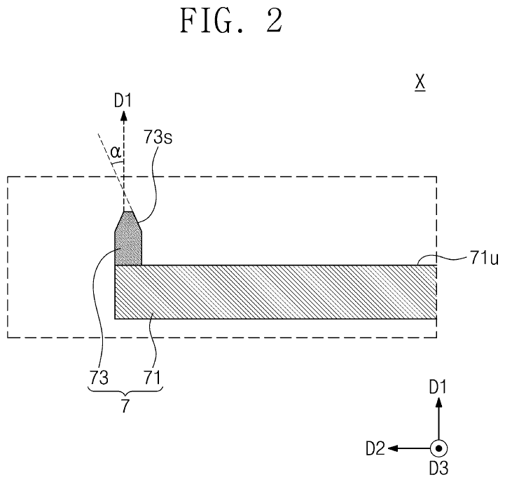

FIG. 2 illustrates an enlarged cross-sectional view showing detail X of FIG. 1.

Referring to FIG. 2, the stage 7 may include a stage body 71 and a substrate support 73.

The stage body 71 may have a circular plate shape. A top surface 71u of the stage body 71 may be, for example, perpendicular to the first direction D1. The stage body 71 may have a first axis (see AX1 of FIG. 1). The first axis AX1 may be parallel to the first direction D1. The first axis AX1 may be a vertical axis.

The substrate support 73 may be positioned on the top surface 71u of the stage body 71. The substrate support 73 may have a support surface 73s. The support surface 73s may be inclined. For example, the support surface 73s may form an acute angle α with the first axis AX1 or an axis of the stage body 71. The acute angle a may range from about 5° to about 80°, but the present inventive concepts are not limited thereto. The support surface 73s may support an edge of a bottom surface of a substrate. Therefore, a bottom surface of a substrate supported on the stage 7 may not be in contact with other substances (e.g., the substrate may contact the support surface 73s of the substrate support but not the top surface 71u of the stage body 71). The substrate support 73 may be provided in plural. The substrate supports of the plurality of substrate supports may be arranged to be spaced apart from each other in a circumferential direction on the stage body 71.

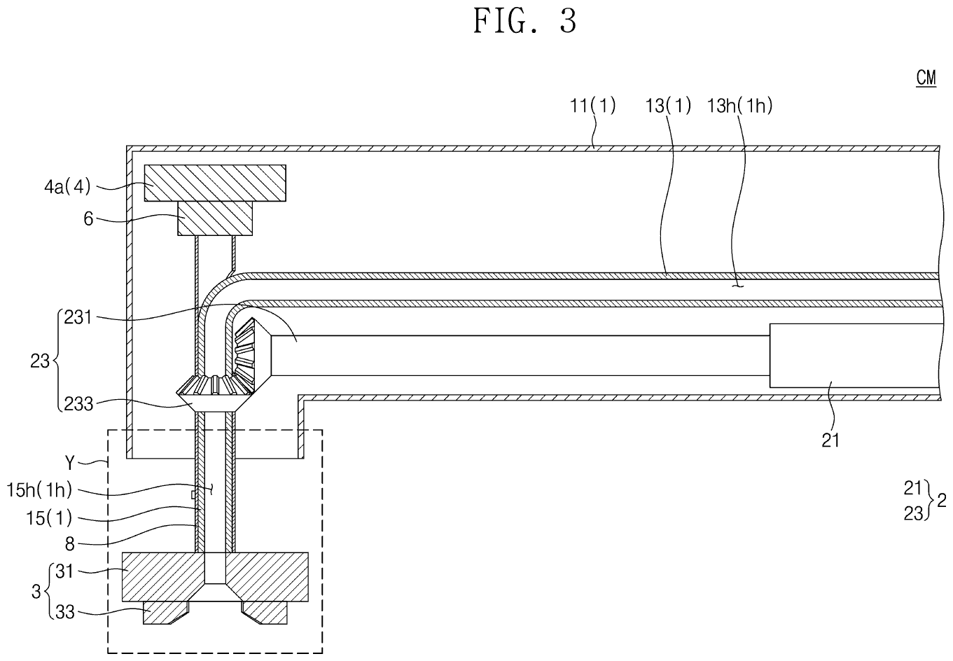

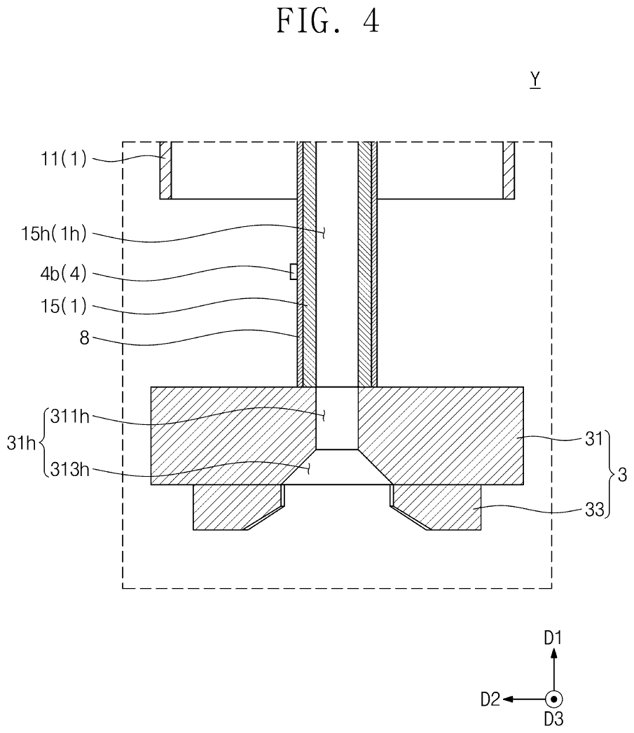

FIG. 3 is a cross-sectional view showing a substrate cleaning module according to some embodiments of the present inventive concepts. FIG. 4 is an enlarged cross-sectional view showing detail Y of FIG. 3.

Referring to FIGS. 3 and 4, the substrate cleaning module CM may include a cleaning arm 1, a substrate cleaning head 3, a connection member 8, a drivetrain 2, a pressure sensor 4, and a pressurization actuator 6.

The cleaning arm 1 may include a housing 11, a first line 13, and a second line 15.

The housing 11 may envelop at least a portion and/or all of the first line 13 and the second line 15. At least a portion of the first line 13 may be positioned in the housing 11. The first line 13 may connect the first fluid supply (see T1 of FIG. 1) to the substrate cleaning head 3. For example, the first line 13 may have a first end connected to a pipeline of the first fluid supply T1. The first line 13 may provide a first portion 13h of a fluid delivery path. For example, the first line 13 may provide a first portion 13h of the fluid delivery path that extends in a horizontal direction. A first end of the first portion 13h of the fluid delivery path may be connected to the first fluid supply T1.

The second line 15 may have a first portion positioned internal to the housing 11 and/or a second portion positioned external to the housing 11. The second line 15 may connect the first fluid supply (see T1 of FIG. 2) to the substrate cleaning head 3. For example, the second line 15 may have a first end connected to a second end of the first line 13. The second line 15 may provide a second portion 15h of the fluid delivery path. For example, the second line 15 may provide a second portion 15h of the fluid delivery path that extends in a vertical direction. A first end of the second portion 15h of the fluid delivery path may be connected to a second end of the first portion 13h of the fluid delivery path. A second end of the second portion 15h of the fluid delivery path may be connected to the substrate cleaning head 3.

The substrate cleaning head 3 may clean a surface of a substrate. The substrate cleaning head 3 may be supported by the cleaning arm 1 and may be configured to move in a horizontal direction. The substrate cleaning head 3 may be combined with the cleaning arm 1. For example, the substrate cleaning head 3 may be secured to the cleaning arm 1 by a joint to allow movement between the substrate cleaning head 3 and the cleaning arm 3. The substrate cleaning head 3 may be connected to the second end of the second line 15. The substrate cleaning head 3 may clean a surface of a substrate. For example, the substrate cleaning head 3 may clean an inactive surface of a substrate while being in contact with the inactive surface of the substrate. The substrate cleaning head 3 may include a support body 31 and a brush 33.

The support body 31 may have a fluid supply channel 31h. The fluid supply channel 31h may vertically penetrate the support body 31 so as to provide a channel between a top surface (see 31u of FIG. 8) of the support body 31 and a bottom surface (see 31b of FIG. 8) of the support body 31. The fluid supply channel 31h may be connected to the second portion 15h of the fluid delivery path. For example, the fluid supply channel 31h may be connected to a bottom end of the second portion 15h of the fluid delivery path. The fluid supply channel 31h may include an upper portion 311h and a lower portion 313h. The upper portion 311h may downwardly extend from the top surface 31u of the support body 31. The lower portion 313h may downwardly extend from the upper portion 311h. The lower portion 313h may extend to the bottom surface 31b of the support body 31. The upper portion 311h may have a constant width. The lower portion 313h may have a width that increases in a downward direction. Thus, a fluid supplied from the second portion 15h of the fluid delivery path may uniformly diffuse in all lateral directions under the support body 31. The support body 31 may be combined with a bottom end (i.e., second end) of the second line 15 and/or a bottom end of the connection member 8. The support body 31 may have a circular plate shape, but the present inventive concepts are not limited thereto.

The brush 33 may be positioned on the bottom surface 31b of the support body 31. When viewed in plan, the brush 33 may not overlap the upper portion 311 of the fluid supply channel. The brush 33 may be provided in plural. The brushes 33 of the plurality of brushes 33 may be arranged to be spaced apart from each other in a circumferential direction about an axis (see AX2 of FIG. 8) of the support body 31. Thus, a gap providing a path between neighboring brushes 33 may exist at the bottom surface of the support body. A constant interval in a circumferential direction may be provided between the brushes 33 of the plurality of brushes 33, but the present inventive concepts are not limited thereto (e.g., each brush 33 may be spaced apart from an adjacent brush 33 by the same distance). The quantity of the brushes 33 of the plurality of brushes 33 may be four to eight. A single brush 33 will be described in the interest of convenience, but the description may be applicable to each brush 33. The brush 33 will be further discussed in detail below.

The connection member 8 may be connected to the support body 31. For example, the connection member 8 may be secured to the top surface 31u of the support body 31. The connection member 8 may extend from the pressurization actuator 6 toward the substrate cleaning head 3. The connection member 8 may couple the pressurization actuator 6 to the support body 31. The connection member 8 may envelop at least a portion of the second line 15.

The drivetrain 2 may rotate the substrate cleaning head 3. The drivetrain 2 may include a motor 21 and a driveline 23. Other types of drivetrains are possible, including a motor connected directly to the substrate cleaning head or a drivetrain including only a driveline connected to an external rotating power source.

The motor 21 may be positioned in the cleaning arm 1. The motor 21 may generate a rotational force (e.g., a torque). The substrate cleaning head 3 may rotate when driven by the rotational force provided from the motor 21. The driveline 23 may connect the motor 21 to the substrate cleaning head 3. The driveline 23 may transfer a torque of the motor 21 to the substrate cleaning head 3. The driveline 23 may include a first power transfer shaft 231 and a second power transfer shaft 233. A first end of the first power transfer shaft 231 may be coupled to the motor 21. The first power transfer shaft 231 may be positioned in the cleaning arm 1. The first power transfer shaft 231 may extend in a horizontal direction. The first power transfer shaft 231 may include a first shaft and a first gear. One end of the second power transfer shaft 233 may be engaged with the first power transfer shaft 231. Another end of the second power transfer shaft 233 may be combined with the substrate cleaning head 3. The second power transfer shaft 233 may vertically extend. The second power transfer shaft 233 may include a second shaft and a second gear. The second shaft may vertically extend to couple with the substrate cleaning head 3. The second gear may be engaged with the first power transfer shaft 231.

The pressure sensor 4 may be connected to the substrate cleaning head 3. For example, the pressure sensor 4 may be connected through the connection member 8 to the substrate cleaning head 3. The pressure sensor 4 may be positioned on the pressurization actuator 6. In this case, a pressure sensor 4a may be connected to the substrate cleaning head 3 through the pressurization actuator 6 and the connection member 8. Alternatively, the pressure sensor 4 may be combined with a lateral surface of the connection member 8. In this case, a pressure sensor 4b may be connected through the connection member 8 to the substrate cleaning head 3. The pressure sensor 4 may gauge a pressure applied to the substrate cleaning head 3 through the connection member 8. The pressure sensor 4 may include a load cell. The load cell may include a strain gauge. For example, the pressure sensor 4 may include a strain gauge combined with a lateral surface of the connection 8.

The pressurization actuator 6 may be positioned on the substrate cleaning head 3. The pressurization actuator 6 may drive the substrate cleaning head 3 to vertically move. The pressurization actuator 6 may be coupled to the substrate cleaning head 3. For example, the pressurization actuator 6 may be coupled to the connection member 8. The pressurization actuator 6 may include an electric actuator such as a linear drive or other actuator such as a pneumatic or hydraulic actuator. When the pressurization actuator 6 presses the connection member 8 downward, the substrate cleaning head 3 may downwardly move.

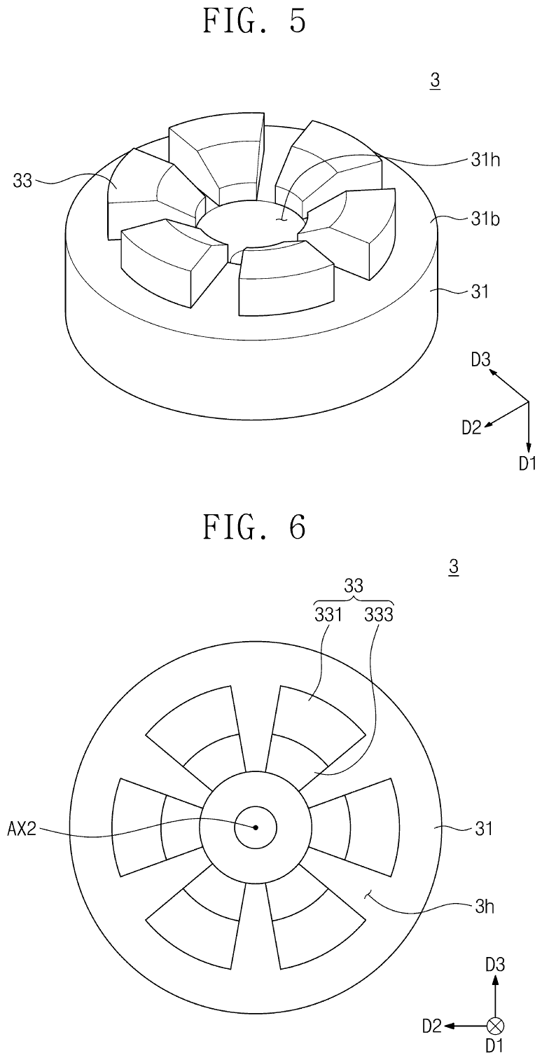

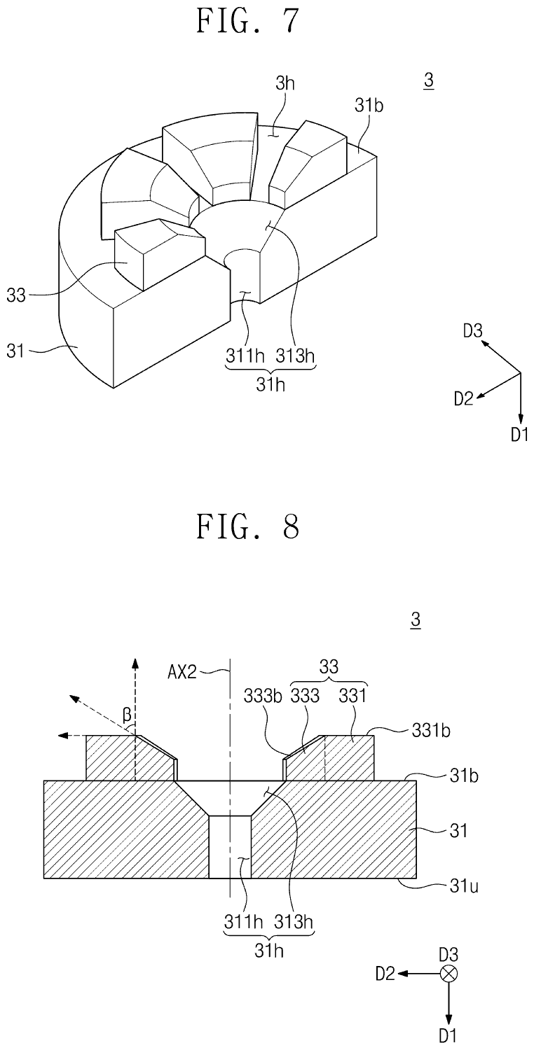

FIG. 5 is a perspective view showing a substrate cleaning head according to some embodiments of the present inventive concepts. FIG. 6 is a bottom view showing a substrate cleaning head according to some embodiments of the present inventive concepts. FIG. 7 is a cut perspective view showing a substrate cleaning head according to some embodiments of the present inventive concepts. FIG. 8 is a cross-sectional view showing a substrate cleaning head according to some embodiments of the present inventive concepts.

Referring to FIGS. 5 to 8, the brush 33 may include a brush body 331 and an inclination portion 333.

The brush body 331 may circumferentially extend to a certain length (the brush body 331 may extend from a first side to a second side opposite the first side to have a partial annular shape). A bottom surface of the brush body 331 may be a planar surface perpendicular to the second axis AX2, which may be a vertical axis of the support body 31. The brush body 331 may have a constant thickness in the first direction (e.g., vertical direction). The brush body 331 may have a porous structure. The brush body 331 may include polyvinyl alcohol (PVA), but the present inventive concepts are not limited thereto.

The inclination portion 333 may extend inward from an inward lateral extent of the brush body 331. The inclination portion 333 may have a thickness that decreases in an inward direction. For example, a bottom surface of the inclination portion 333 may be an inclined surface 333b that makes an acute angle β with the second axis AX2. The acute angle β formed between the inclined surface 333b and the second axis AX2 may range from about 10° to about 80°, but the present inventive concepts are not limited thereto. The inclination portion 333 may have a porous structure. The inclination portion 333 may include polyvinyl alcohol (PVA), but the present inventive concepts are not limited thereto.

An inner end line of the bottom surface of the brush body 331 may be located at a level substantially the same as or similar to that of a lower end of the inclined surface 333b. For example, the inner end line may be coincident with a bottom end of the inclined surface 333b. The brush body 331 and the inclination portion 333 may be integrally formed as a single unitary piece. A width in a radius direction of the brush body 331 may be less than a width in a radius direction of the inclination portion 333. Therefore, particles introduced under the bottom surface of the brush body 331 (i.e., between the brush body 331 and a substrate being cleaned) may be promptly discharged toward a region under the inclined surface 333b.

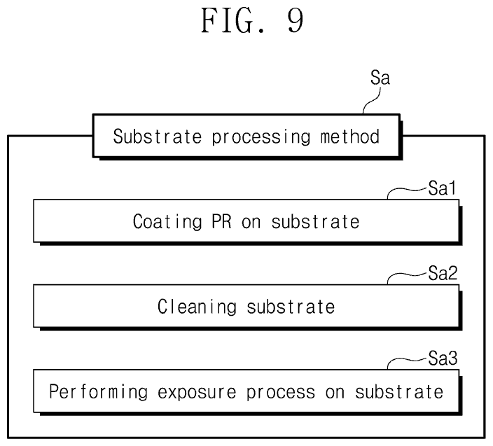

FIG. 9 is a flow chart showing a substrate processing method according to some embodiments of the present inventive concepts.

Referring to FIG. 9, an example of a substrate processing method Sa is described. The substrate processing method Sa may include coating a photoresist (PR) on a substrate (Sa1), cleaning the substrate (Sa2), and performing an exposure process on the substrate (Sa3).

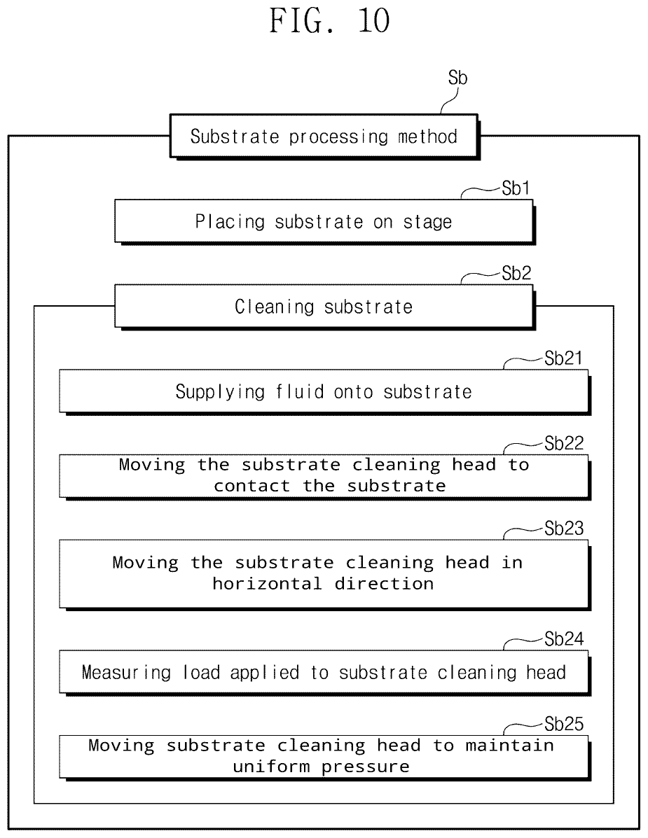

FIG. 10 is a flow chart showing a substrate processing method according to some embodiments of the present inventive concepts.

Referring to FIG. 10, a substrate processing method Sb is described. The substrate processing method Sb of FIG. 10 may be an example of performing the substrate cleaning step Sa2 in the substrate processing method Sa discussed with reference to FIG. 9. The substrate processing method Sb of FIG. 10 is an example of processing a substrate which may be performed using the substrate cleaning system SA discussed with reference to FIGS. 1 to 8. The substrate processing method Sb may include placing a substrate on a stage (Sb1) and cleaning the substrate (Sb2).

The substrate cleaning step Sb2 may include supplying a fluid onto a substrate (Sb21), moving a substrate cleaning head to contact the substrate (Sb22), moving the substrate cleaning head in a horizontal direction (Sb23) relative to the substrate, measuring a pressure applied to the substrate cleaning head (Sb24), and moving the substrate cleaning head vertically from the substrate (Sb25).

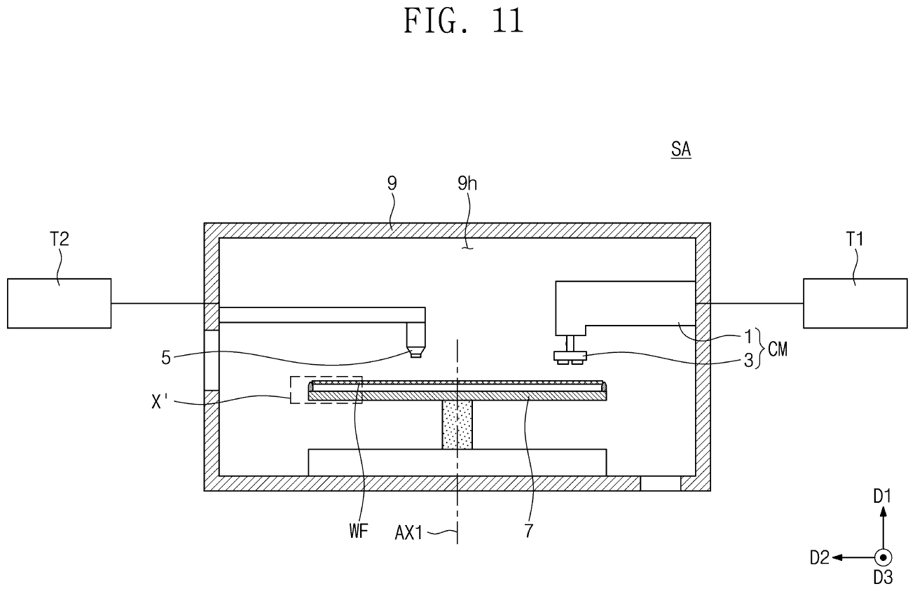

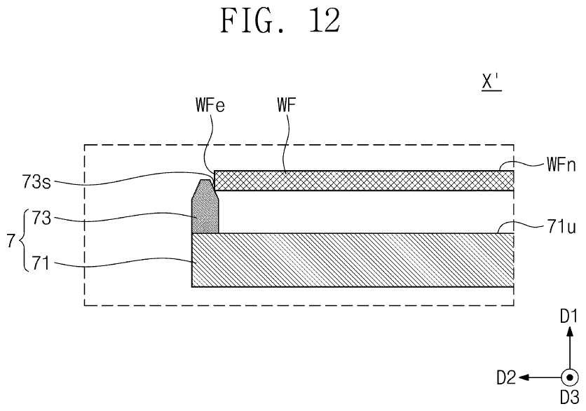

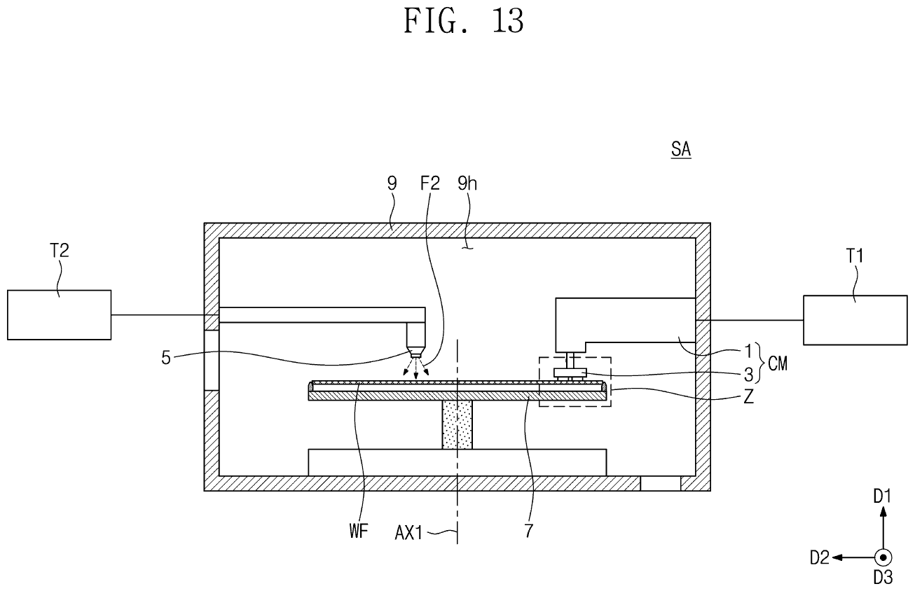

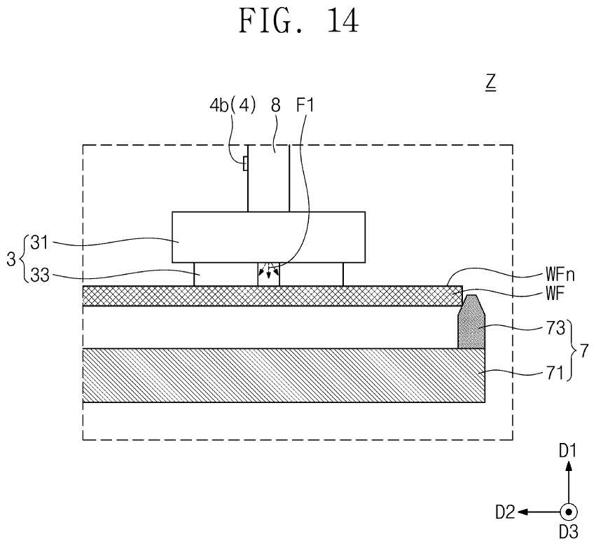

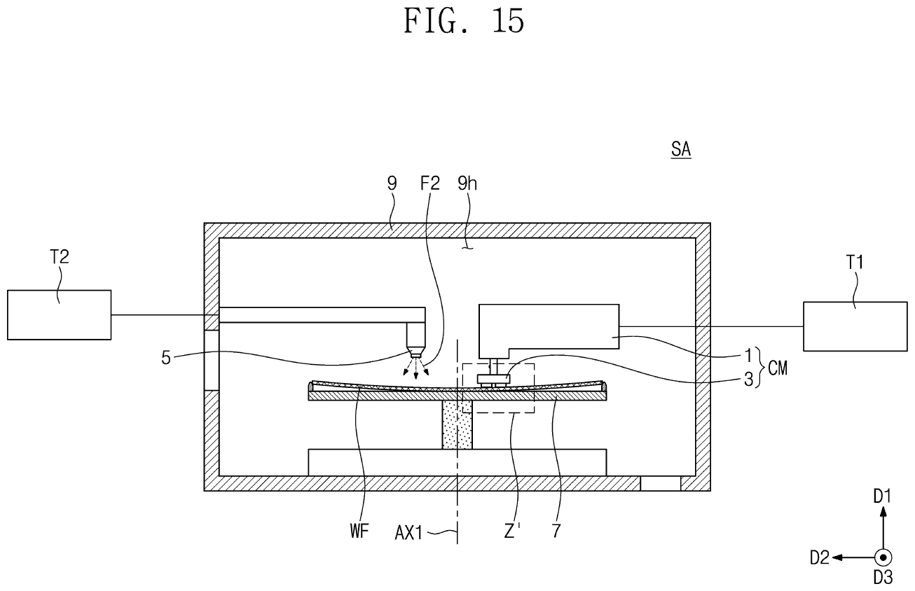

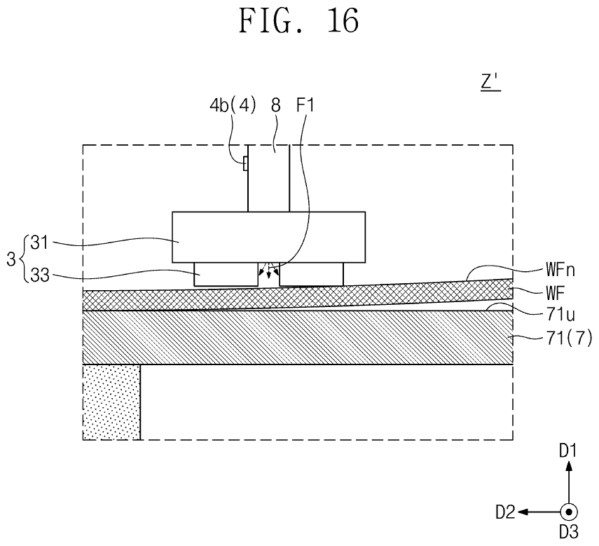

With reference to FIGS. 11 to 16, the following will describe a substrate processing method according to the flow chart of FIG. 10.

FIGS. 11 to 16 illustrate diagrams showing a substrate processing method according to the flow chart of FIG. 10.

Referring to FIGS. 10, 11, and 12, the substrate placement step Sb1 may include placing a substrate WF on the substrate support 73 with the active surface of the substrate W facing downwards (e.g., facing away from the substrate cleaning head). For example, with the substrate placed on the substrate support 73, a bottom surface of the substrate WF may be the active surface and a top surface of the substrate WF may be the inactive surface WFn. The bottom surface of the substrate WF may have an edge WFe supported by the support surface 73s of the substrate support 73. The bottom surface of the substrate WF may be spaced above and apart from a top surface 71u of the stage body 71.

Referring to FIGS. 10, 13, and 14, the fluid supply step Sb21 may include supplying a first fluid F1 onto the substrate WF and supplying a second fluid F2 onto the substrate WF.

The supplying of the first fluid F1 onto the substrate WF may include using the substrate cleaning head 3 to supply the first fluid F1 onto the top surface of the substrate WF. For example, in some embodiments, a compressor of the first fluid supply may pressurize the first fluid F1 causing the first fluid F1 to flow through the pipeline of the first fluid supply to a first end of the first portion 13h of the fluid delivery path. The first fluid F1 supplied from the first fluid supply T1 may be sprayed through the fluid supply channel (see 31h of FIG. 4) onto the substrate WF. A flow of the first fluid F1 from the fluid supply channel may cause particles on the substrate WF that are positioned between brushes 33 of the substrate cleaning head 3 to be pushed outwardly from the substrate cleaning head 3. The first fluid F1 may include one or more of hydrogen peroxide, ammonia, and deionized water, but the present inventive concepts are not limited thereto.

The supplying of the second fluid F2 onto the substrate WF may include using the cleaning solution injection device 5 to supply the second fluid F2 onto the substrate WF. For example, in some embodiments, a compressor of the second fluid supply may pressurize the second fluid F1 causing the second fluid F1 to flow through the pipeline of the second fluid supply to the cleaning solution injection device 5. The second fluid F2 supplied from the second fluid supply T2 may be sprayed through the cleaning solution injection device 5 onto the substrate WF. Outside the substrate cleaning head 3, the second fluid F2 may clean the top surface of the substrate WF. A flow of the second fluid F2 may cause particles on the substrate WF that are located outside the substrate cleaning head 3 to be pushed outwardly from the substrate WF. In this step, the stage 7 may rotate the substrate WF. The second fluid F2 may include one or more of hydrogen peroxide, ammonia, and deionized water, but the present inventive concepts are not limited thereto.

The substrate contact step Sb22 may include moving the brush 33 to contact the top surface of the substrate WF. The bottom surface (see 331b of FIG. 8) of the brush body (see 331 of FIG. 8) may be in contact with the top surface of the substrate WF. The drivetrain (see 2 of FIG. 3) may drive the substrate cleaning head 3 to rotate on the substrate WF. Therefore, particles on the top surface of the substrate WF may escape from the bottom surface 331b of the brush body 331 to move along the inclined surface 333b.

Referring to FIGS. 10, 15, and 16, the horizontal movement step Sb23 may include moving the cleaning arm 1 in a horizontal direction to allow the substrate cleaning head 3 to move toward a center of the substrate WF. At the center of the substrate WF, the substrate cleaning head 3 may be in contact with the substrate WF.

The pressure measurement step Sb24 may include measuring a pressure applied to the substrate cleaning head 3 when the pressure actuator presses the substrate cleaning head 3 against the substrate WF is pressurized. The load measurement step Sb24 may be performed by the pressure sensor 4, which may be a load cell. In some embodiments, due to deflection of the substrate near the center, if the substrate cleaning head 3 is maintained at a constant vertical position, a relatively small pressure may be applied by the substrate cleaning head 3 to the center of the substrate WF.

The vertical movement step Sb25 may include moving the substrate cleaning head 3 vertically based on the measured pressure applied to the substrate cleaning head 3. For example, at the center of the substrate WF, the pressurization actuator (see 6 of FIG. 3) may drive the substrate cleaning head 3 to move downwards to maintain a uniform pressure applied by the substrate cleaning head to the substrate WF. Thus, even when the center of the substrate WF drops downwards, the substrate cleaning head 3 may uniformly pressurize the substrate WF.

According to a substrate cleaning head, a substrate cleaning module including the same, a substrate cleaning system including the same, and a substrate processing method using the same in accordance with some embodiments of the present inventive concepts, a pressure sensor may be used to measure a pressure applied to the substrate cleaning head, and the substrate cleaning head may be moved vertically move based on the measured load. Thus, even when a substrate drops downwards on a center thereof, the substrate may be pressurized at a constant force by the substrate cleaning head. For example, the center and edge of the substrate may be pressurized at the same pressure. Therefore, the substrate may be uniformly cleaned. Accordingly, it may be possible to prevent contaminant from remaining at a specific position on the substrate.

According to a substrate cleaning head, a substrate cleaning module including the same, a substrate cleaning system including the same, and a substrate processing method using the same in accordance with some embodiments of the present inventive concepts, a brush may include an inclination portion to prevent particles from being caught under the brush. When a contact area between the brush and a substrate is reduced due to a small width of a brush body, it may be possible to more effectively prevent particles from being caught under the brush. It may thus be possible to suppress back contamination, such as substrate scratches caused by particles caught under the brush.

According to a substrate cleaning head, a substrate cleaning module including the same, a substrate cleaning system including the same, and a substrate processing method using the same in accordance with some embodiments of the present inventive concepts, a fluid may be sprayed outside the substrate cleaning head and particles that escape from the substrate cleaning head may be completely pushed outwardly from a substrate. Accordingly, a cleaning process may be effectively performed.

According to a substrate cleaning head, a substrate cleaning module including the same, a substrate cleaning system including the same, and a substrate processing method using the same of the present inventive concepts, a substrate may be cleaned while being uniformly pressurized and contaminants may be prevented from remaining on a specific position on the substrate.

According to a substrate cleaning head, a substrate cleaning module including the same, a substrate cleaning system including the same, and a substrate processing method using the same of the present inventive concepts, a substrate may be prevented from being contaminated back in a cleaning procedure.

According to a substrate cleaning head, a substrate cleaning module including the same, a substrate cleaning system including the same, and a substrate processing method using the same of the present inventive concepts, a substrate may be prevented from damage in a cleaning procedure.

Effects of the present inventive concepts are not limited to the mentioned above, other effects which have not been mentioned above will be clearly understood to those skilled in the art from the following description.

Although the present invention has been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

1. A substrate cleaning head, comprising:
a support body having a vertical axis; and
a plurality of brushes at a bottom surface of the support body, wherein the brushes of the plurality of brushes are arranged in a circumferential direction about the vertical axis of the support body,
wherein the brushes of the plurality of brushes are each spaced apart from one another in the circumferential direction,
wherein each brush of the plurality of brushes includes:
a brush body that extends in the circumferential direction from a first side surface to a second side surface opposing the first side surface; and
an inclination portion extending inward from an inward lateral extent of the brush body,
wherein a thickness of the inclination portion decreases in an inward direction toward a center of the support body, and
wherein an inclined surface of a bottom surface of the inclination portion forms an acute angle with the vertical axis.

2. The substrate cleaning head of claim 1, wherein the support body has a fluid supply channel that penetrates through the support body in a vertical direction from a top surface of the support body to the bottom surface of the support body.

3. The substrate cleaning head of claim 2, wherein the fluid supply channel includes:
an upper portion that extends downwardly from the top surface of the support body; and
a lower portion that extends downwardly from the upper portion to the bottom surface of the support body,
wherein a width of the lower portion increases in a downward direction.

4. The substrate cleaning head of claim 1, wherein
a bottom surface of the brush body is a planar surface perpendicular to the vertical axis,
an inner end line of the bottom surface of the brush body is at a level that is the same as a level of a lower end of the inclined surface, and the inner end line is connected to the lower end of the inclined surface.

5. The substrate cleaning head of claim 1, wherein each brush of the plurality of brushes is spaced apart from an adjacent brush of the plurality of brushed at a constant interval in the circumferential direction.

6. The substrate cleaning head of claim 1, wherein the acute angle between the inclined surface and the vertical axis is in a range from 10° to 80°.

7. The substrate cleaning head of claim 1, wherein the quantity of brushes of the plurality of brushes is in the range of four to eight.

8. The substrate cleaning head of claim 1, wherein each of the brush body and the inclination portion includes polyvinyl alcohol (PVA).

9. The substrate cleaning head of claim 1, wherein the brush body and the inclination portion are formed as a single unitary piece.

10. The substrate cleaning head of claim 1, wherein a width in a radius direction of the brush body is less than a width in the radius direction of the inclination portion.

11. A substrate cleaning module, comprising:
a substrate cleaning head configured to clean a surface of a substrate;
a cleaning arm supporting the substrate cleaning head and configured to move the substrate cleaning head in a horizontal direction;
a pressure sensor connected to the substrate cleaning head and configured to measure a pressure applied to the substrate cleaning head; and
a pressurization actuator connected to the substrate cleaning head and configured to drive the substrate cleaning head vertically,
wherein the substrate cleaning head includes:
a support body; and
a brush on a bottom surface of the support body.

12. The substrate cleaning module of claim 11, wherein the pressure sensor includes a load cell.

13. The substrate cleaning module of claim 12, further comprising a connection arm that extends from the pressurization actuator toward the substrate cleaning head and connects the pressurization actuator to the support body,
wherein the load cell includes a strain gauge connected with a lateral surface of the connection arm.

14. The substrate cleaning module of claim 11, wherein
the support body has a fluid supply channel that penetrates the support body from a top surface to a lower surface of the support body, and
the cleaning arm has a fluid delivery path connected to the fluid supply channel.

15. The substrate cleaning module of claim 11, further comprising a drivetrain configured to rotate the substrate cleaning head,
wherein the drivetrain includes:
a motor in the cleaning arm; and
a driveline that connects the motor to the substrate cleaning head and is configured to transfer a torque of the motor to the substrate cleaning head, and
wherein the driveline includes:
a first power transfer shaft with a first end connected to the motor and that extends in a horizontal direction in the cleaning arm; and
a second power transfer shaft that extends in a vertical direction with a first end of the second power transfer shaft engaged with a second end of the first power transfer shaft and a second end of the second power transfer shaft connected with the substrate cleaning head.

16. A substrate cleaning system, comprising:
a stage that supports a substrate;
a substrate cleaning module on the stage; and
a cleaning solution injection device above the stage and spaced apart in a horizontal direction from the substrate cleaning module,
wherein the substrate cleaning module includes:
a substrate cleaning head; and
a cleaning arm that supports the substrate cleaning head,
wherein the substrate cleaning head includes:
a support body; and
a plurality of brushes on a bottom surface of the support body and each brush of the plurality of brushed spaced apart from an adjacent brush in a circumferential direction about a vertical axis of the support body,
wherein the support body provides a fluid supply channel that penetrates the support body in a vertical direction from a top surface to a bottom surface, and
wherein the cleaning arm has a fluid delivery path connected to the fluid supply channel.

17. The substrate cleaning system of claim 16, wherein the fluid delivery path includes:
a first portion that extends in the horizontal direction; and
a second portion that extends downwardly in a vertical direction from one end of the first portion and is connected to the fluid supply channel.

18. The substrate cleaning system of claim 16, further comprising:
a first fluid supply that is connected to the fluid delivery path and supplies the fluid delivery path with a first fluid; and
a second fluid supply that is connected to the cleaning solution injection device and supplies the cleaning solution injection device with a second fluid.

19. The substrate cleaning system of claim 16, wherein the stage includes:
a stage body; and
a plurality of substrate support members on a top surface of the stage body,
wherein each of the plurality of substrate support members includes a support surface that is inclined to form an acute angle with a vertical axis of the stage body.

20. The substrate cleaning system of claim 19, wherein the substrate cleaning module includes:
a load cell that is connected to the substrate cleaning head and measures a load applied to the substrate cleaning head; and
a pressurization actuator that is connected to the substrate cleaning head and drives the substrate cleaning head to move vertically.

21-25. (canceled)
